(19) United States
(12) Patent Application Publication
(10) Pub. No.: US 2023/0336153 A1
(43) Pub. Date: Oct. 19, 2023

(54) MULTILAYER INTERDIGITAL TRANSDUCER ELECTRODE FOR SURFACE ACOUSTIC WAVE DEVICE

(71) Applicant: Skyworks Solutions, Inc., Irvine, CA (US)

(72) Inventors: Rei Goto, Osaka-Shi (JP); Hironori Fukuhara, Ibaraki-Shi (JP); Yuya Hiramatsu, Neyagawa-Shi (JP)

(21) Appl. No.: 18/188,808

(22) Filed: Mar. 23, 2023

Related U.S. Application Data
(60) Provisional application No. 63/323,279, filed on Mar. 24, 2022.
(60) Provisional application No. 63/323,259, filed on Mar. 24, 2022.

(51) Int. Cl. H03H 9/145; H03H 9/25

(52) U.S. Cl. CPC H03H 9/14541; H03H 9/1457; H03H 9/25

(57) ABSTRACT

An acoustic wave device is disclosed. the acoustic wave device is configured to generate a wave having a wavelength of L. The acoustic wave device includes a piezoelectric layer a first layer of an interdigital transducer electrode over the piezoelectric layer, and a second layer of the interdigital transducer electrode over the first layer. The first layer has a material with a first mass density of ρ. The first mass density of ρ is greater than 5000 kg/m³. The first layer has a thickness of t1 less than 0.04 L. The first layer can have the thickness of t1 in a range between 0.0025 L(10220/ρ) and 0.04 L(10220/ρ). The second layer has a material with a second mass density that is smaller than the first mass density.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/323,279, filed Mar. 24, 2022, titled “ACOUSTIC WAVE DEVICE WITH MULTILAYER INTERDIGITAL TRANSDUCER ELECTRODE,” and U.S. Provisional Patent Application No. 63/323,259, filed Mar. 24, 2022, titled “MULTILAYER INTERDIGITAL TRANSDUCER ELECTRODE FOR SURFACE ACOUSTIC WAVE DEVICE,” are hereby incorporated by reference under 37 CFR 1.57 in their entirety.

### BACKGROUND

### Technical Field

Embodiments of this disclosure relate to acoustic wave devices.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

### SUMMARY

The innovations described in the claims each have several aspects, no single one of which is solely responsible for its desirable attributes. Without limiting the scope of the claims, some prominent features of this disclosure will now be briefly described.

In one aspect, an acoustic wave device configured to generate a wave having a wavelength of L is disclosed. The acoustic wave device can include a piezoelectric layer, a first layer of an interdigital transducer electrode formed with the piezoelectric layer, and a second layer of the interdigital transducer over the first layer. The first layer has a first material with a first mass density. The first material has a normalized mechanical loading exchange rate normalized by a mechanical loading exchange rate of molybdenum. The first layer has a thickness less than 0.04 L multiplied by the normalized mechanical loading exchange rate of the first material. The second layer has a second material with a second mass density smaller than the first mass density.

In one embodiment, the first layer of the interdigital transducer electrode is disposed on the piezoelectric layer.

In one embodiment, the first material is molybdenum and the thickness of the first layer is in a range between 0.0025 L and 0.04 L.

In one embodiment, the first material is tungsten and the thickness of the first layer is in a range between 0.001337 L and 0.02 L.

In one embodiment, the first mass density is greater than 8500 kg/m³.

In one embodiment, the first mass density is greater than 10000 kg/m³.

In one embodiment, the acoustic wave device further includes a functional layer below the piezoelectric layer and a support substrate layer below the functional layer. The second material can be aluminum, the functional layer can be a silicon dioxide layer, and the support layer can be a silicon layer.

In one embodiment, the acoustic wave device further includes a passivation layer over the interdigital transducer electrode. The passivation layer can be a silicon nitride layer. The passivation layer can have a first region that is positioned at least partially over an edge region and a gap region of the interdigital transducer electrode, and a second region that is positioned over a center region of the interdigital transducer electrode and has a thickness greater than a thickness of the first region.

In one embodiment, the interdigital transducer electrode includes a hammer head shape at an edge region of the interdigital transducer electrode.

In one embodiment, the interdigital transducer electrode includes a thicker interdigital transducer electrode portion at an edge region of the interdigital transducer electrode that has a thickness greater than other portions of the interdigital transducer electrode.

In one aspect, an acoustic wave device configured to generate a wave having a wavelength of L is disclosed. The acoustic wave device can include a piezoelectric layer, a first layer of an interdigital transducer electrode formed with the piezoelectric layer, and a second layer of the interdigital transducer electrode over the first layer. The first layer has a first material with a first mechanical loading exchange rate. The second layer has a second material with a second mechanical loading exchange rate smaller than the first mechanical loading exchange rate. A thickness of the first layer and a thickness of the second layer are configured so as to increase electromechanical coupling coefficient of the wave generated by the acoustic wave device relative to the thickness of the first layer being 0.

In one embodiment, the first layer has a thickness less than 0.04 L multiplied by a normalized mechanical loading exchange rate of the first material that is normalized by a mechanical loading exchange rate of molybdenum. The first material can include molybdenum and the second layer can include aluminum. The thickness of the first layer can be in a range between 0.0025 L and 0.04 L. The first material can include tungsten and the second material can include aluminum. The thickness of the first layer can be in a range between 0.001337 L and 0.02 L.

In one embodiment, the acoustic wave device further includes a passivation layer over the interdigital transducer electrode. The passivation layer can be a silicon nitride layer, and the interdigital transducer electrode can include a hammer head shape at an edge region of the interdigital transducer electrode.

In one aspect, a surface acoustic wave device configured to generate a wave having a wavelength of L is disclosed. The acoustic wave device can include a multilayer piezoelectric substrate including a lithium tantalate layer, a first layer of an interdigital transducer electrode formed with the multilayer piezoelectric substrate, and a second layer of the interdigital transducer electrode over the first layer. The first layer includes molybdenum, tungsten, or platinum, the first layer has a thickness less than 0.04 L. The second layer has a material with a mass density smaller than a mass density of the first layer.

In one aspect, an acoustic wave device configured to generate a wave having a wavelength of L is disclosed. The acoustic wave device can include a piezoelectric layer, a first layer of an interdigital transducer electrode formed with the piezoelectric layer, and a second layer of the interdigital transducer electrode over the first layer. The first layer has a material with a first mass density. The first mass density is greater than 5000 kg/m³. The first layer has a thickness less than 0.04 L. The second layer has a material with a second mass density smaller than the first mass density.

In one embodiment, the first layer of the interdigital transducer electrode is disposed on the piezoelectric layer.

In one embodiment, the first mass density is greater than 8500 kg/m³. The first mass density can be greater than 10000 kg/m³ and the thickness of the first layer can be less than 0.03 L. The first mass density can be greater than 15000 kg/m³. The thickness of the first layer can be less than 0.008 L.

In one embodiment, the second material is aluminum and the first mass density is greater than 10000 kg/m³. The thickness of the first layer can be in a range between 0.0025 L and 0.03 L.

In one embodiment, the acoustic wave device further includes a functional layer below the piezoelectric layer and a support substrate layer below the functional layer. The functional layer can be a silicon dioxide layer and the support layer can be a silicon layer.

In one embodiment, the acoustic wave device further includes a passivation layer over the interdigital transducer electrode. The passivation layer can have a first region that is positioned over an edge region and a gap region of the interdigital transducer electrode, and a second region that is positioned over a center region of the interdigital transducer electrode and has a thickness greater than a thickness of the first region.

In one embodiment, the interdigital transducer electrode includes a hammer head shape at an edge region of the interdigital transducer electrode.

In one embodiment, the interdigital transducer electrode includes a thicker interdigital transducer electrode portion at an edge region of the interdigital transducer electrode that has a thickness greater than other portions of the interdigital transducer electrode.

In one aspect, an acoustic wave device configured to generate a wave having a wavelength of L is disclosed. The acoustic wave device can include a piezoelectric layer, a first layer of an interdigital transducer electrode structure formed with the piezoelectric layer, a second layer of the interdigital transducer structure over the first layer, and a support substrate layer below the piezoelectric layer. The first layer has a material with a mass density greater than 8500 kg/m³. The first layer has a thickness less than 0.03 L. The second layer is an aluminum layer.

In one embodiment, the first mass density is greater than 10000 kg/m³.

In one embodiment, the acoustic wave device further includes a passivation layer over the interdigital transducer electrode. The passivation layer can be a silicon nitride layer. The passivation layer can have a first region that is positioned over an edge region and a gap region of the interdigital transducer electrode, and a second region that is positioned over a center region of the interdigital transducer electrode and has a thickness greater than a thickness of the first region. The interdigital transducer electrode can include a hammer head shape at an edge region of the interdigital transducer electrode.

In one aspect, an acoustic wave device configured to generate a wave having a wavelength of L is disclosed. The acoustic wave device can include a piezoelectric layer, a first layer of an interdigital transducer electrode formed with the piezoelectric layer, and a second layer of the interdigital transducer electrode over the first layer. The first layer has a material with a first mass density of ρ. The first mass density of ρ is greater than 5000 kg/m³. The first layer has a thickness of t1 in a range between 0.0025 L(10220/ρ) and 0.04 L(10220/ρ). The second layer has a material with a second mass density smaller than the first mass density.

In one embodiment, the first mass density of ρ is greater than 8500 kg/m³. The first mass density of ρ can be greater than 10000 kg/m³ and the thickness of t1 is less than 0.03 L(10220/ρ).

The present disclosure relates to U.S. Patent Application No. ______ [Attorney Docket SKYWRKS.1169A1], titled “ACOUSTIC WAVE DEVICE WITH MULTILAYER INTERDIGITAL TRANSDUCER ELECTRODE,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1 is a schematic cross-sectional side view of a surface acoustic wave (SAW) device according to an embodiment.

FIG. 2 is a graph showing simulated electromechanical coupling coefficients (k²) of the SAW device of FIG. 1.

FIG. 3A is a graph showing the total thickness of an interdigital transducer (IDT) electrode used in simulations of FIG. 2.

FIG. 3B is a graph showing thicknesses of the first and second layers of the IDT electrode used in the simulations of FIG. 2.

FIG. 3C is a graph showing resonance frequency of the SAW device used in the simulations of FIG. 2.

FIG. 3D is a graph showing simulated stopband widths of the SAW device used in the simulations of FIG. 2.

FIG. 4A is a graph showing measured compressional velocities (Vp) and shear velocities (Vs) of the SAW device of FIG. 1.

FIG. 4B is a graph showing measured quality factor (Q) of the SAW device of FIG. 1.

FIG. 5A is a graph showing wavelengths L of surface acoustic wave generated by the SAW device of FIG. 1.

FIG. 5B is a graph showing simulated electromechanical coupling coefficients (k²) of the SAW device of FIG. 1.

FIG. 6A is a schematic cross sectional side view of a SAW device according to an embodiment.

FIG. 6B is a schematic top plan view of the SAW device of FIG. 6A.

FIG. 6C is a graph showing simulation results of a conventional SAW device and the SAW device illustrated in FIGS. 6A and 6B.

FIG. 7A is a schematic cross sectional side view of a SAW device according to another embodiment.

FIG. 7B is a schematic top plan view of the SAW device of FIG. 7A.

FIG. 7C is a graph showing simulation results of a conventional SAW device and the SAW device illustrated in FIGS. 7A and 7B.

FIG. 7D is a schematic cross sectional side view of a SAW device according to another embodiment.

FIG. 7E is a schematic top plan view of the SAW device of FIG. 7D.

FIG. 7F is a graph showing simulation results of a conventional SAW device and the SAW device 4 illustrated in FIGS. 7D and 7E.

FIG. 8A is a schematic diagram of a transmit filter that includes a surface acoustic wave resonator according to an embodiment.

FIG. 8B is a schematic diagram of a receive filter that includes a surface acoustic wave resonator according to an embodiment.

FIG. 9 is a schematic diagram of a radio frequency module that includes a surface acoustic wave resonator according to an embodiment.

FIG. 10 is a schematic diagram of a radio frequency module that includes filters with surface acoustic wave resonators according to an embodiment.

FIG. 11 is a schematic block diagram of a module that includes an antenna switch and duplexers that include a surface acoustic wave resonator according to an embodiment.

FIG. 12A is a schematic block diagram of a module that includes a power amplifier, a radio frequency switch, and duplexers that include a surface acoustic wave resonator according to an embodiment.

FIG. 12B is a schematic block diagram of a module that includes filters, a radio frequency switch, and a low noise amplifier according to an embodiment.

FIG. 13A is a schematic block diagram of a wireless communication device that includes a filter with a surface acoustic wave resonator in accordance with one or more embodiments.

FIG. 13B is a schematic block diagram of another wireless communication device that includes a filter with a surface acoustic wave resonator in accordance with one or more embodiments.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Any features of the SAW resonators discussed herein can be implemented in any suitable SAW device.

Size reduction of certain SAW devices may be desired. One solution for reducing a size of a SAW device can include implementation of a relative dense material for an interdigital transducer electrode (IDT) electrode of the SAW device. For example, a multilayer IDT electrode structure that include two or more metal layers can be implemented in a SAW device to reduce the size of the SAW device.

In general, high quality factor (Q), large effective electromechanical coupling coefficient (k²), high frequency ability, and spurious free response can be significant aspects for acoustic wave elements to enable low-loss filters, delay lines, stable oscillators, and sensitive sensors.

When the multilayer IDT electrode structure having a light layer and a heavy layer that has a material that is more dense than a material of the light layer is implemented in the SAW device, the quality factor (Q) of the SAW device may be degraded as compared to a SAW that includes only the light layer.

Embodiments of this disclosure relate to SAW devices with a multilayer IDT electrode structure that provide improved effective electromechanical coupling coefficient (k²) while maintaining a relatively high quality factor (Q) and a small device size as compared to a SAW device with a single layer IDT.

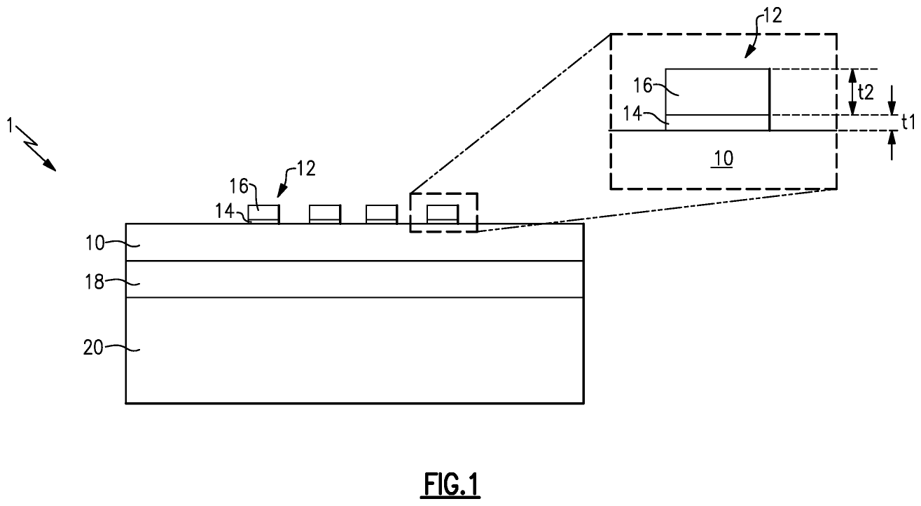

FIG. 1 is a schematic cross-sectional side view of a surface acoustic wave (SAW) device 1 according to an embodiment. The illustrated SAW device 1 can include a piezoelectric layer 10, an interdigital electrode transducer (IDT) electrode 12 that includes a first layer 14 and a second layer 16 formed with (e.g., disposed on or over) the piezoelectric layer 10, a functional layer 18 below the piezoelectric layer 10, and a support substrate 20 below the functional layer 18. The IDT electrode 12 is a multilayer IDT electrode. The SAW device 1 can include a multilayer piezoelectric substrate (MPS) structure. The SAW device 1 generates a surface acoustic wave having a wavelength λ or L.

The piezoelectric layer 10 can include any suitable piezoelectric layer, such as a lithium based piezoelectric layer. In some embodiments, the piezoelectric layer 10 can be a lithium tantalate (LT) layer. In some other embodiments, the piezoelectric layer 10 can be a lithium niobate (LN) layer. For example, the piezoelectric layer 10 can be an LT layer having a cut angle of 42° (42° Y-cut X-propagation LT) or a cut angle of 60° (60° Y-cut X-propagation LT). For example, the piezoelectric layer 10 can be 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. A thickness of the piezoelectric layer 10 can be selected based on a wavelength λ or L of a surface acoustic wave generated by the SAW device 1 in certain applications. The piezoelectric layer 10 can be sufficiently thick to avoid significant frequency variation. For example, the thickness of the piezoelectric layer 10 can be in a range of 0.1 L to 0.5, 0.1 L to 0.3 L, or 0.1 L to 0.2 L. Selecting the thickness of the piezoelectric layer 10 from these ranges can be critical in avoiding significant frequency variation and providing sufficient temperature coefficient of frequency for the SAW device 1.

The illustrated IDT electrode 12 includes a first layer 26 and a second layer 28. In the SAW device 1, the IDT electrode 12 can include separate IDT layers that impact acoustic properties and electrical properties. Accordingly, in some applications, electrical properties, such as insertion loss, can be improved by adjusting one of the IDT layers without significantly impacting acoustic properties.

The first layer 14 of the IDT electrode 12 can be referred to as a lower electrode layer. The first layer 14 of the IDT electrode 12 is disposed between the second layer 16 of the IDT electrode 12 and the piezoelectric layer 10. As illustrated, the first layer 14 of the IDT electrode 12 has a first side in physical contact with the piezoelectric layer 10 and a second side in physical contact with the second layer 28 of the IDT electrode 12. Depending on the material selected and the application, the first layer 14 can impact acoustic properties of the SAW device 1.

The second layer 16 of the IDT electrode 12 can be referred to as an upper electrode layer. The second layer 16 of the IDT electrode 12 is disposed over the first layer 14 of the IDT electrode 12. In some embodiments, the SAW device 1 can include a temperature compensation layer (not illustrated) over the second layer 16. As illustrated, the second layer 16 of the IDT electrode 12 has a first side in physical contact with the first layer 26 of the IDT electrode 12 and a second side opposite the first side. Depending on the material selected and the application, the second layer 16 of the IDT electrode 12 can impact electrical properties of the SAW resonator 1.

The IDT electrode 12 can include any suitable IDT electrode material. For example, the IDT electrode can include molybdenum (Mo), aluminum (Al), copper (Cu), Magnesium (Mg), titanium (Ti), tungsten (W), the like, or any suitable combination thereof. The IDT electrode 12 may include alloys, such as AlMgCu, AlCu, etc. In some embodiments, for example, the first layer 14 can be molybdenum (Mo) and the second layer 16 can be aluminum (Al), or the first layer 14 can be tungsten (W) and the second layer 16 can be aluminum (Al).

The first layer 14 has a thickness t1 and the second layer 16 has a thickness t2. The thickness t1 of the first layer 14 and the thickness t2 of the second layer 16 can be determined based at least in part on the wavelength L of surface acoustic wave generated by the SAW device 1. In some embodiments, the thickness t1 of the first layer 14 can be in a range between 0.0025 L and 0.04 L or 0.0025 L and 0.03 L. For example, the thickness t1 of the first layer 14 can be in a range between 0.0025 L and 0.035 L, 0.0025 L and 0.025 L, 0.0025 L and 0.02 L, 0.0025 L and 0.01 L, 0.005 L and 0.025 L, 0.01 L and 0.025 L, or 0.005 L and 0.02 L. In some embodiments, the thickness t2 of the second layer 16 can be in a range between 0.036 L and 0.12 L or 0.04 L and 0.12 L. For example, the thickness t2 of the second layer 16 can be in a range between 0.04 L and 0.1 L, 0.04 L and 0.075 L, 0.05 L and 0.012 L, 0.07 L and 0.012 L, 0.05 L and 0.01 L, or 0.05 L and 0.075 L. Selecting the thicknesses t1, t2 of the first and second layers 14, 16 from these ranges can be critical in providing improved effective electromechanical coupling coefficient (k²) while maintaining a relatively high quality factor (Q) and a small device size as compared to a SAW device with a single layer IDT.

In some embodiments, a width of the first layer 14 can be different from a width of the second layer 16. For example, the width of the first layer 14 can be greater than a width of the second layer 16. Though the illustrated IDT electrode 12 is located on a surface the piezoelectric layer 10, in some other embodiments, the IDT electrode 12 can be at least partially within the piezoelectric layer 10 or embedded (e.g., completely surrounded within) in the piezoelectric layer 10.

The illustrated surface acoustic wave resonator 1 includes the functional layer 18. The functional layer 18 can be a single crystal layer. In some embodiments, the functional layer 18 can be an SiO₂ layer. In some embodiment, the functional layer 18 can function as an adhesion layer. In some embodiments, a thickness of the functional layer 18 can be the same as, generally similar to, or thinner than the thickness of the piezoelectric layer 10.

The support substrate 20 can be a single crystal layer. The support substrate 20 can include, for example, silicon (Si), sapphire, aluminum oxide (Al₂O₃), aluminum nitride (AlN), ceramic material, etc. The support substrate 20 can have a high impedance relative to the piezoelectric layer 10 and high thermal conductivity. For example, the support substrate 20 can have a higher impedance than an impedance of the piezoelectric layer 10 and a higher thermal conductivity than a thermal conductivity of the piezoelectric layer 10. The support substrate 20 can include a trap rich layer that may be formed at or near a surface of the support substrate 20 facing the functional layer 18. One or more additional layers can be inserted between the functional layer 18 and the support substrate 20 to improve the electrical performance to prevent or mitigate the unwanted electrical leakage on the surface of the support substrate 20. For example, one or more layers that include Poly-Si, Amorphas Si, Porous Si, SiN, and/or AlN can be disposed between the functional layer 18 and the support substrate 20.

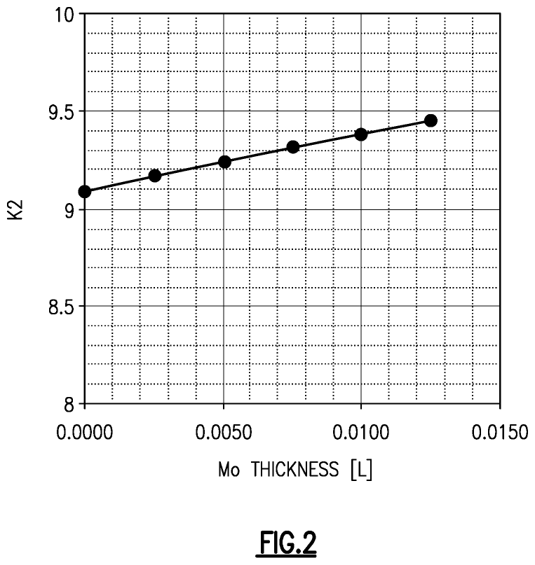

FIG. 2 is a graph showing simulated electromechanical coupling coefficients (k²) of the SAW device 1 illustrated in FIG. 1 with various thicknesses t1, t2 of the first and second layers 14, 16 of the IDT electrode 12. The thicknesses t1, t2 of the first and second layers 14, 16 of the IDT electrode 12 used in the SAW device 1 are selected so as to have the same resonant frequency in each simulation. In the simulations, molybdenum is used as the first layer 14 and aluminum is used as the second layer 16. Table 1 shown below is a list of the thicknesses t1, t2 used in the simulations.

TABLE 1

| t1 [L] | t2 [L] |
|---|---|
| 0.0000 | 0.1124 |
| 0.0025 | 0.1086 |
| 0.0050 | 0.1044 |
| 0.0075 | 0.0997 |
| 0.0100 | 0.0946 |
| 0.0125 | 0.0890 |

The simulation results indicate that the IDT electrode 12 with the first layer 14 provides a higher electromechanical coupling coefficients (k²) than the IDT electrode 12 without the first layer 14. The simulation results indicate that the electromechanical coupling coefficients (k²) improves as the thickness t1 of the first layer 14 increases. The higher electromechanical coupling coefficients (k²) can be beneficial for obtaining an improved filter pass band width.

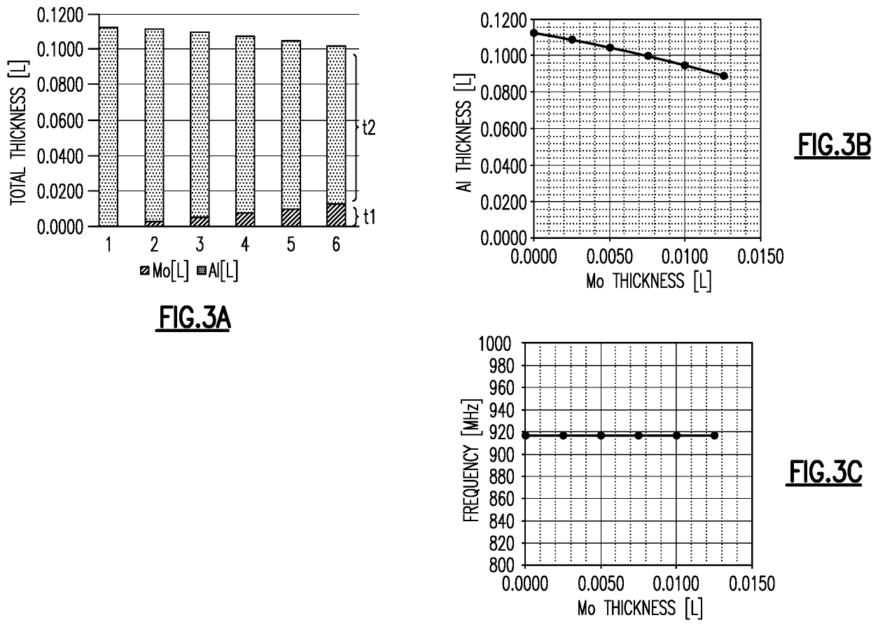

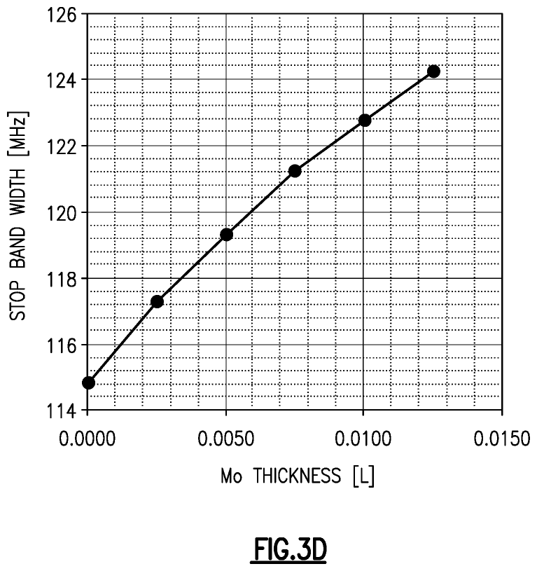

FIG. 3A is a graph showing the total thickness (sum of the thicknesses t1, t2) of the IDT electrode 12 used in the simulations of FIG. 2. FIG. 3B is a graph showing the thicknesses t1, t2 of the first and second layers 14, 16 of the IDT electrode 12 used in the simulations of FIG. 2. FIG. 3C is a graph showing the resonance frequency of the SAW device 1 used in the simulations of FIG. 2. FIG. 3D is a graph showing simulated stopband widths of the SAW device 1 used in the simulations of FIG. 2. The simulation results shown in FIG. 2 and the graphs of FIGS. 3A-3C indicates that the SAW device 1 with the first layer 14 can enable the total thickness of the IDT electrode 12 smaller while improving the electromechanical coupling coefficients (k²) for generating the same resonant frequency. Accordingly, the first layer 14 can enable the SAW device 1 to reduce its size relative to a SAW device without the first layer 14. The simulated stopband widths of the SAW device 1 indicates that the stopband width increases as the thickness t1 of the first layer 14 increases. The stopband width can be proportional to the reflection coefficient. A larger reflection coefficient can contribute to smaller IDT electrode size.

When the first layer 14 is a relatively dense metal layer, such as molybdenum, increasing the thickness t1 of the first layer 14 can contribute to an improving structural durability. Therefore, the IDT electrode 12 with the first layer 14 can enable a relatively high power handling as compared to a single IDT structure. In some embodiments, a cross-sectional area of the first layer 14 can be as large as, or less than a cross-sectional area of the second layer 16.

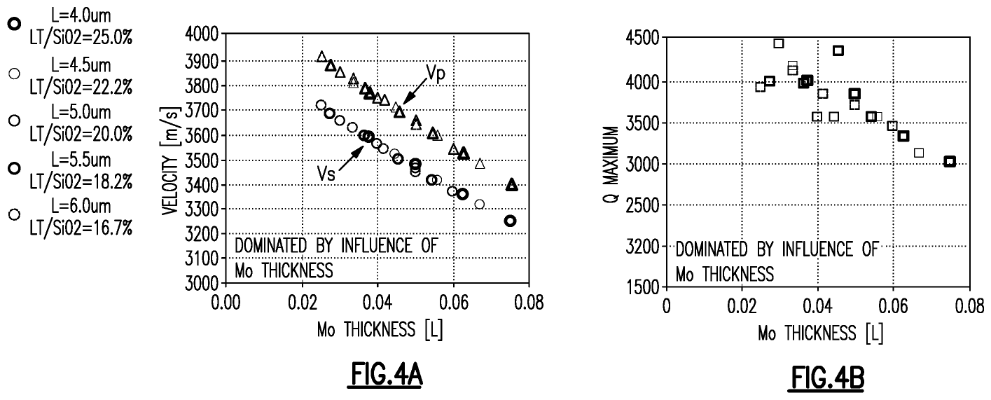

FIG. 4A is a graph showing measured acoustic wave velocity of resonant and anti-resonant Vs and Vp defined as Vs=fs*L, Vp=fp*L, in which fs is resonant frequency, and fp is anti-resonant frequency of the SAW device 1 with various IDT thicknesses and wavelengths L of surface acoustic wave. FIG. 4B is a graph showing measured quality factor (Q) of the SAW device 1 with various IDT thicknesses and wavelengths L of surface acoustic wave. In the measurements, lithium tantalate (LT) is used as the piezoelectric layer, molybdenum is used as the first layer 14 of the IDT electrode 12, and silicon dioxide (SiO₂) is used as the functional layer 18. The measurement results indicate that the thickness t1 of the first layer 14 can affect the Q; Q decreases as the thickness t1 of the first layer 14 increases. The measurement results indicate that SAW device 1 with the thickness t1 of 0.03 L or less can maintain relatively high Q. The Q may be improved by, for example, altering a physical structure of the IDT electrode 12. Some other simulations indicate that, in various embodiments, the thickness t1 of about 0.04 L or less can maintain relative high Q.

The first layer of the IDT electrode 12 disclosed herein can enable a SAW device to have a relatively high electromechanical coupling coefficients (k²) and a reduced size, while maintaining a relatively high quality factor (Q). The thickness t1 can be in a range between 0.0025 L and 0.04 L, 0.0025 L and 0.03 L, 0.0025 L and 0.025 L, 0.0025 L and 0.02 L, 0.0025 L and 0.01 L, 0.005 L and 0.025 L, 0.01 L and 0.025 L, or 0.005 L and 0.02 L, to obtain the advantages disclosed herein. The thickness t1 of the first layer 14 can be selected based at least in part on the material (e.g., a mass density property of a material) of the first layer 14 to obtain the advantages disclosed herein.

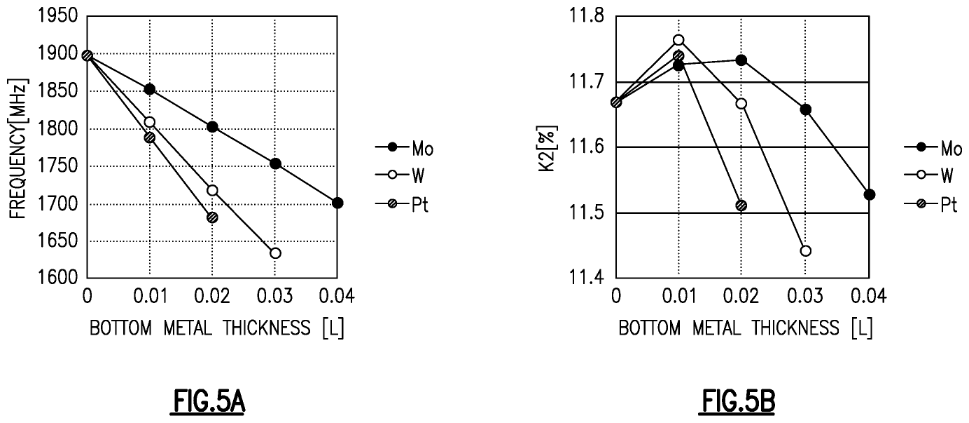

FIG. 5A is a graph showing wavelengths L of surface acoustic wave generated by the SAW device 1 with various thicknesses t1 and materials of the first layer 14. FIG. 5B is a graph showing simulated electromechanical coupling coefficients (k²) of the SAW device 1 with various thicknesses t1 and materials of the first layer 14. In the simulations, molybdenum, tungsten, and platinum were separately used as the first layer 14 of the IDT electrode 12. The simulations are run with the thicknesses t1 of 0 L, 0.01 L, 0.02 L, 0.03 L, and 0.04 L. The results of FIG. 5A shows that using platinum enables the most size reduction amongst the three materials used in the simulations. The results of FIG. 5A can suggest that a more dense material used for the first layer 14 can enable more size reduction, in some applications. In some embodiments, a material of the first layer 14 can be selected to have a more mass density than a mass density of a material used for the second layer 16.

The simulated electromechanical coupling coefficient (k²) results indicate that thickness t1 of about 0.014 L or less can provide improved k² when platinum is used for the first layer 14, thickness t1 of about 0.016 L or less can provide improved k² when tungsten is used for the first layer 14, and thickness t1 of about 0.03 L or less can provide improved k² when molybdenum is used for the first layer 14. A mass loading exchange rate can be determined based on a material of the first layer 14 and a mass loading effect provided by the material of the first layer 14. Some other simulations indicate that, in various embodiments, thickness t1 of about 0.018 L or less can provide improved k² when platinum is used for the first layer 14, thickness t1 of about 0.0.2 L or less can provide improved k² when tungsten is used for the first layer 14, and thickness t1 of about 0.4 L or less can provide improved k² when molybdenum is used for the first layer 14.

For the SAW device 1, a normalized mass loading exchange rates of aluminum (Al), molybdenum (Mo), tungsten (W), platinum (Pt), ruthenium (Ru), titanium (Ti), copper (Cu), and gold (Au), normalized by the mass loading exchange rate of the molybdenum is provided in Table 2 shown below. Table 2 also shows mass densities and Yong's moduli of the materials.

TABLE 2

| | Exchange rate | Density | Young's modulus |
|---|---|---|---|
| Material | normalized by Mo | ρ[kg/m3] | E[N/m\hat{ }2] |
| Al | 0.47 | 2690 | 6.773E+10 |
| Mo | 1.00 | 10220 | 3.654E+11 |
| W | 1.87 | 19300 | 3.450E+11 |
| Pt | 2.27 | 17700 | 1.520E+11 |
| Ru | 1.17 | 12410 | 4.140E+11 |
| Ti | 0.57 | 4500 | 1.161E+11 |
| Cu | 1.03 | 8930 | 1.297E+11 |
| Au | 2.68 | 19300 | 8.085E+10 |

The mass loading exchange rate of the material can generally be proportional to the mass density of the material. In some embodiments, the thickness t1 of the first layer 14 can be determined at least in part on the normalized mass loading exchange rate shown in Table 2. For example, the thickness t1 of the first layer 14 can be in a range between 0.0025 L and 0.04 L, 0.0025 L and 0.03 L, 0.0025 L and 0.025 L, 0.0025 L and 0.02 L, 0.0025 L and 0.01 L, 0.005 L and 0.025 L, 0.01 L and 0.025 L, or 0.005 L and 0.02 L, multiplied by the normalized mass loading exchange rate normalized by the mass loading exchange rate of molybdenum to obtain the advantages disclosed herein. In some embodiments, the thickness t1 of the first layer 14 can be determined at least in part on the density of a material. For example, the thickness t1 of the first layer 14 can be in a range between 0.0025 L and 0.04 L, 0.0025 L and 0.03 L, 0.0025 L and 0.025 L, 0.0025 L and 0.02 L, 0.0025 L and 0.01 L, 0.005 L and 0.025 L, 0.01 L and 0.025 L, or 0.005 L and 0.02 L, multiplied by (10220/ρ) in which ρ is the density of the material used for the first layer 14. In other words, the thickness t1 can be in a range as calculated by the following equation (Equation 1), in which x can be 0.0025, 0.005, or 0.01, and y can be 0.03, 0.025, 0.02, or 0.01.

x*L*(10220/ρ)≤t1<y*L*(10220/ρ) . . . (Equation 1)

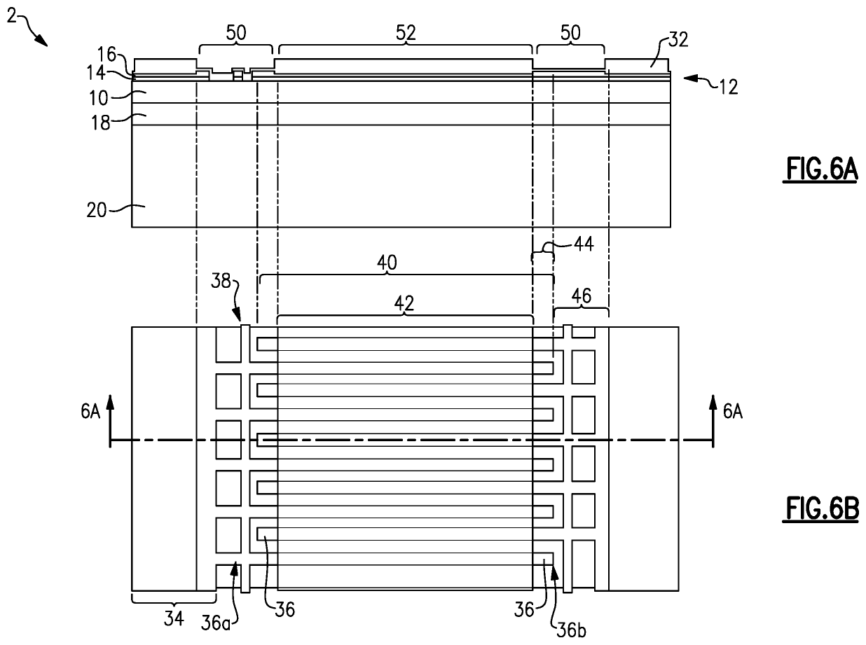

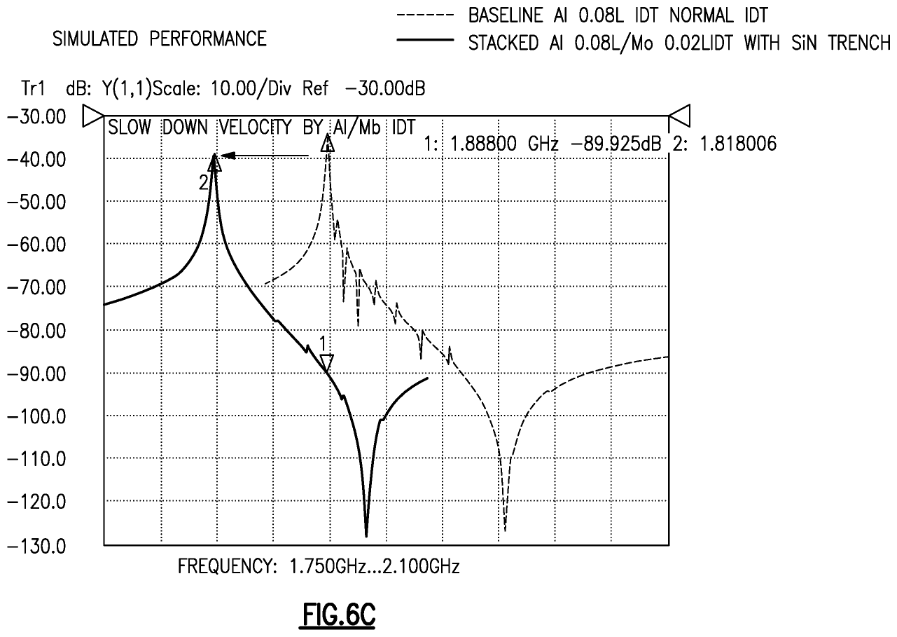

FIG. 6A is a schematic cross sectional side view of a surface acoustic wave (SAW) device 2 according to an embodiment. FIG. 6B is a schematic top plan view of the SAW device 2 of FIG. 6A. The dashed lines between FIGS. 6A and 6B show relative positions of the illustrated components. Unless otherwise noted, the components of FIGS. 6A and 6B may be similar to or the same as like numbered components of FIG. 1. The SAW device 2 includes a piezoelectric layer 10, an IDT electrode 12 over the piezoelectric layer 10, a dispersion adjustment layer 32 over the IDT electrode 12. The dispersion adjustment layer 32 can serve as a passivation layer and/or a trimming layer for frequency trimming. The illustrated SAW device 2 of FIGS. 6A and 6B includes two bus bars 34 and five fingers 36 extending from each of the bus bars 34. Any suitable number of fingers for a particular application can extend from the bus bars.

Each finger 36 has a proximate end 36a that is in contact with a bus bar 34 and a distal end 36b opposite the proximate end 36a. A body portion 36c of the finger 36 extends between the proximate end 36a and the distal end 36b. A portion near the distal end 36b can be referred as an edge portion. The IDT electrode 12 includes an active region 40 that has a center region 42 and an edge region 44, and a gap region 46 between the active region 40 and the bus bar 34. The edge region 44 can be a region near the distal end 36b. In some embodiments, the edge region 44 is a region of the finger within 0.5 L to 1.2 L from the distal end 36b of the finger 36. The IDT electrode 12 includes a mini bus bar 38 in the gap region 46. The mini bus bar 38 can extend perpendicular to a longitudinal direction of the fingers 36. In the illustrated embodiment, the minibus bar 38 includes a continuous line. In some other embodiments, the mini bus bar 38 can include a disconnected portions in the gap region 46. In some embodiments, the mini bust bar 38 can be disconnected from the bus bar 34. The mini bus bar 38 can contribute to suppressing a transverse mode. The mini bus bar 38 is an example of a piston mode structure that suppresses a transverse mode.

The dispersion adjustment layer 32 can be a silicon nitride (SiN) layer disposed at least partially over the IDT electrode 12. The dispersion adjustment layer 32 (e.g., a SiN layer) may be completely disposed over the IDT electrode 12. In certain applications, the dispersion adjustment layer 21 can include another suitable material, such as a silicon oxynitride (SiON) layer, in place of the illustrated SiN layer to increase the magnitude of the velocity of the underlying region of the SAW resonator 1. According to some applications, the dispersion adjustment layer 32 can include SiN and another material. The dispersion adjustment layer 32 can also function as a passivation layer in some embodiments.

The dispersion adjustment layer 32 can cause a magnitude of the velocity in the underlying region of the SAW device 2 to be increased. The portions uncovered by the dispersion adjustment layer 32 can reduce velocity in the underlying region of the SAW device 2 relative to regions covered by the dispersion adjustment layer 32 to thereby suppress transverse modes. For example, as shown in FIGS. 6A and 6B, the dispersion adjustment layer 32 can have a thin region 50 over the edge region 44 and the gap region 46, and a thick region that has a thickness greater than a thickness of the thin region over the center region 42.

FIG. 6C is a graph showing simulation results of a conventional SAW device and the SAW device 2 illustrated in FIGS. 6A and 6B. The conventional SAW used in the simulation includes a single layer aluminum IDT electrode that has a thickness of 0.08 L without a dispersion adjustment layer. The SAW device 2 used in the simulation includes molybdenum as the first layer 14 and aluminum as the second layer 16. The first layer 14 used in the simulation has a thickness t1 of 0.02 L, and the second layer 16 used in the simulation has a thickness t2 of 0.08 L. The simulation results of FIG. 6C indicates that the dispersion adjustment layer 32 can contribute to suppressing the transverse mode.

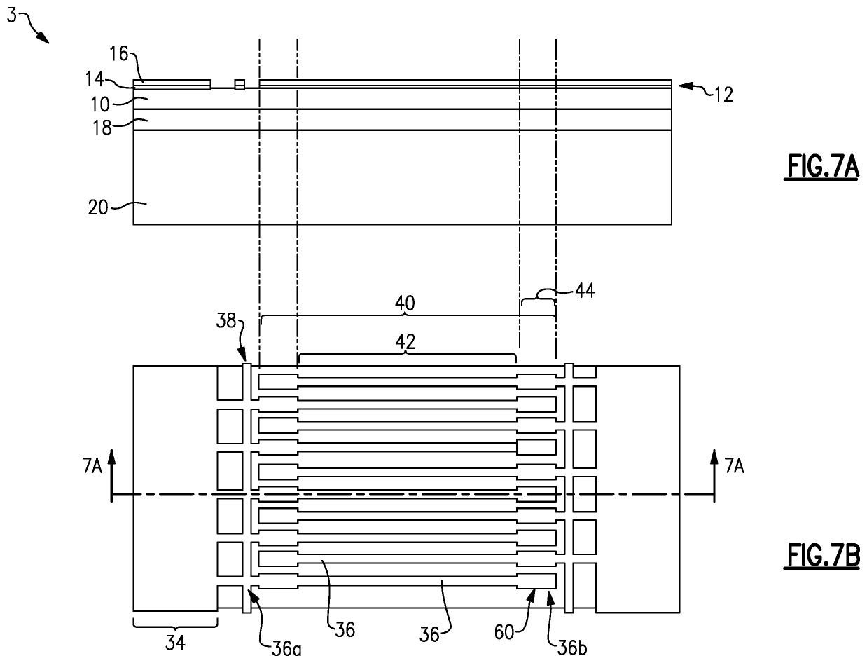

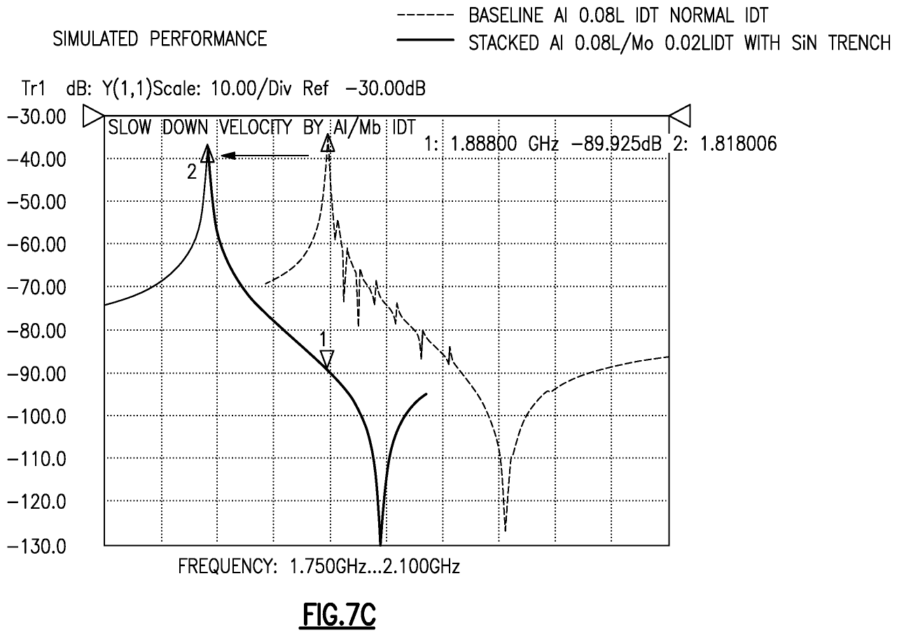

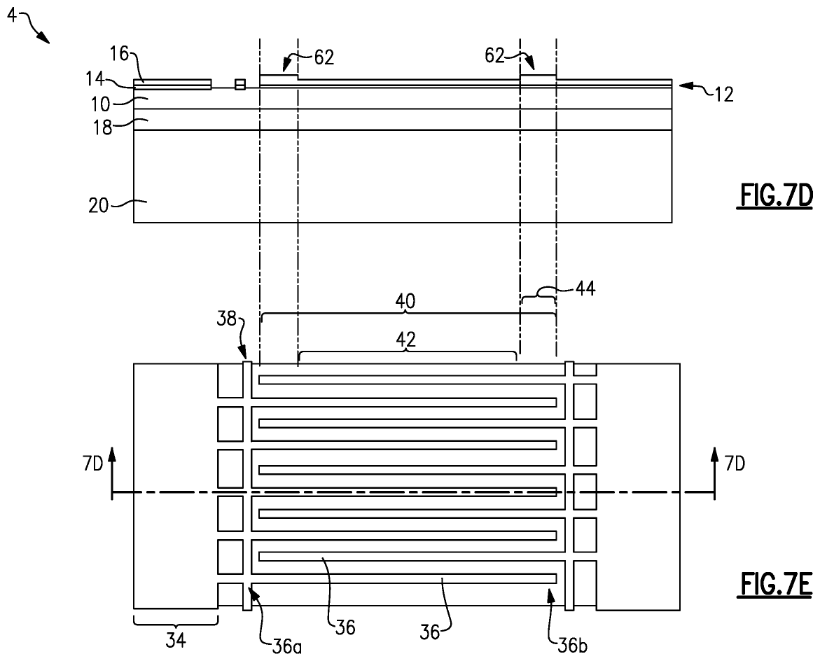

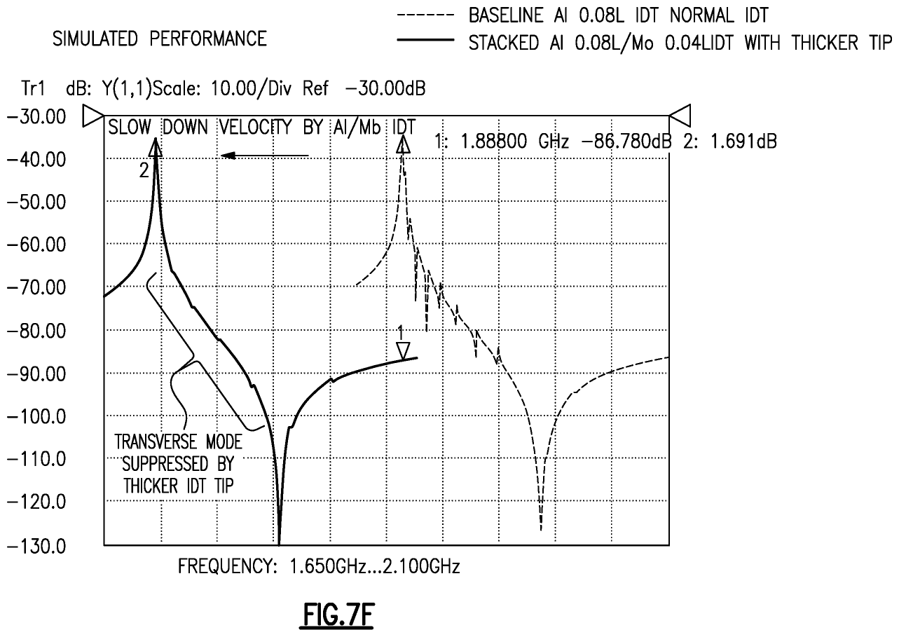

FIG. 7A is a schematic cross sectional side view of a surface acoustic wave (SAW) device 3 according to an embodiment. FIG. 7B is a schematic top plan view of the SAW device 3 of FIG. 7A. The dashed lines between FIGS. 7A and 7B show relative positions of the illustrated components. Unless otherwise noted, the components of FIGS. 7A and 7B may be similar to or the same as like numbered components of FIGS. 1, 6A, and 6B. The SAW device 3 includes a piezoelectric layer 10, an IDT electrode 12 over the piezoelectric layer 10, a dispersion adjustment layer 32 over the IDT electrode 12. The SAW device 3 includes bus bars 34 and fingers 36 extending from each of the bus bars 34.

The IDT electrode 12 can have a hammer head shape 60 at or near the edge region 44. The hammer head shape 60 can provide a velocity difference between the edge region 44 and the central region 42 of an active region 40 of the IDT electrode 12, thereby facilitating a piston mode operation. The IDT electrode 12 can also include a mini bus bar 38 in the gap region 44. The mini bus bar 38 can contribute to suppressing a transverse mode. The hammer head shape 60 and the mini bus bar 38 are examples of piston mode structures that suppress a transverse mode. The edge region 44 can have an edge region width in a range between 0.5 L and 1.2 L, in some embodiments. The IDT electrode 12 has an edge duty factor that is calculated by dividing the edge width by L/2, in which L represents the wavelength. The edge duty factor can be in a range between 0.4 to 0.6 or 0.55 to 0.7, in some embodiments.

FIG. 7C is a graph showing simulation results of a conventional SAW device and the SAW device 3 illustrated in FIGS. 7A and 7B. The conventional SAW used in the simulation includes a single layer aluminum IDT electrode that has a thickness of 0.08 L without a dispersion adjustment layer. The SAW device 3 used in the simulation includes molybdenum as the first layer 14 and aluminum as the second layer 16. The first layer 14 used in the simulation has a thickness t1 of 0.02 L, and the second layer 16 used in the simulation has a thickness t2 of 0.08 L. The IDT electrode 12 of the SAW device 3 used in the simulation has an edge region width of 0.75 L, and the edge duty factor of 0.6. The simulation results of FIG. 7C indicates that the hammer head shape 60 can suppress the transverse mode.

FIG. 7D is a schematic cross sectional side view of a surface acoustic wave (SAW) device 4 according to an embodiment. FIG. 7E is a schematic top plan view of the SAW device 4 of FIG. 7D. The dashed lines between FIGS. 7A and 7B show relative positions of the illustrated components. Unless otherwise noted, the components of FIGS. 7D and 7E may be similar to or the same as like numbered components of FIGS. 1, 6A, 6B, 7A, and 7B. The SAW device 4 includes a piezoelectric layer 10, an IDT electrode 12 over the piezoelectric layer 10, a dispersion adjustment layer 32 over the IDT electrode 12. The SAW device 4 includes bus bars 34 and fingers 36 extending from each of the bus bars 34.

The IDT electrode 12 can have a thicker IDT edge 62 at or near the edge region 44. The thicker IDT edge 62 has a thickness that is greater than a thickness of other regions of the IDT electrode 12. In some embodiments, the thickness t1 of the first layer 14 and/or the thickness t2 of the second layer 16 can be adjusted to form the thicker IDT edge 62. The thicker IDT edge 62 can provide a velocity difference between the edge region 44 and the central region 42 of an active region 40 of the IDT electrode 12, thereby facilitating a piston mode operation. The IDT electrode 12 can also include a mini bus bar 38 in the gap region 44. The mini bus bar 38 can contribute to suppressing a transverse mode. The thicker IDT edge 62 and the mini bus bar 38 are examples of piston mode structures that suppress a transverse mode.

FIG. 7F is a graph showing simulation results of a conventional SAW device and the SAW device 4 illustrated in FIGS. 7D and 7E. The conventional SAW used in the simulation includes a single layer aluminum IDT electrode that has a thickness of 0.08 L without a dispersion adjustment layer. The SAW device 4 used in the simulation includes molybdenum as the first layer 14 and aluminum as the second layer 16. The first layer 14 used in the simulation has a thickness t1 of 0.04 L, and the second layer 16 used in the simulation has a thickness t2 of 0.08 L. The simulation results of FIG. 7C indicates that the thicker IDT edge 62 can suppress the transverse mode, thereby improving the quality factor (Q).

A SAW device (e.g., an MPS SAW resonator) including any suitable combination of features disclosed herein be included in a filter arranged to filter a radio frequency signal in a fifth generation (5G) New Radio (NR) operating band within Frequency Range 1 (FR1). A filter arranged to filter a radio frequency signal in a 5G NR operating band can include one or more MPS SAW resonators disclosed herein. FR1 can be from 410 MHz to 7.125 GHz, for example, as specified in a current 5G NR specification. In 5G applications, the thermal dissipation of the MPS SAW resonators disclosed herein can be advantageous. For example, such thermal dissipation can be desirable in 5G applications with a higher time-division duplexing (TDD) duty cycle compared to fourth generation (4G) Long Term Evolution (LTE). One or more MPS SAW resonators in accordance with any suitable principles and advantages disclosed herein can be included in a filter arranged to filter a radio frequency signal in a 4G LTE operating band and/or in a filter having a passband that includes a 4G LTE operating band and a 5G NR operating band.

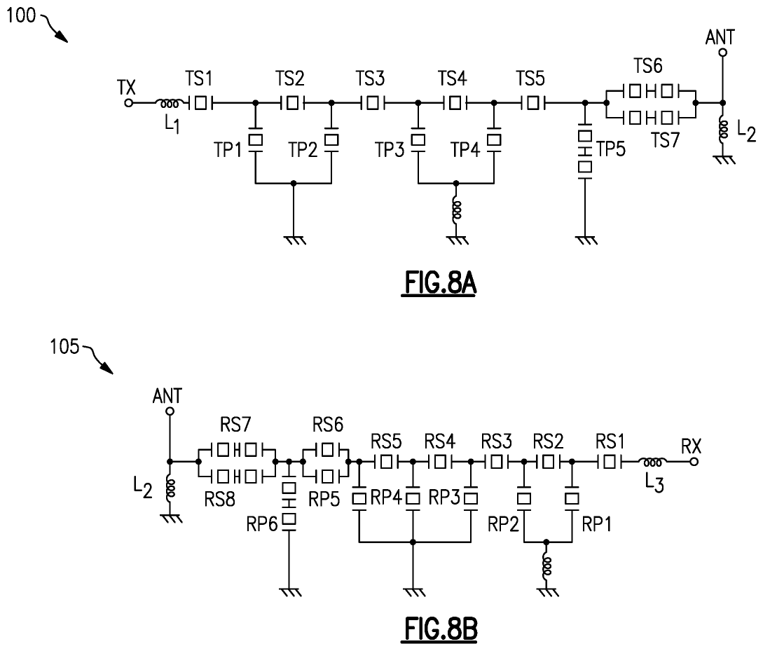

FIG. 8A is a schematic diagram of an example transmit filter 100 that includes surface acoustic wave resonators according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be a SAW resonator in accordance with any suitable principles and advantages disclosed herein. For instance, one or more of the SAW resonators of the transmit filter 100 can be a surface acoustic wave device disclosed herein. Alternatively or additionally, one or more of the SAW resonators of the transmit filter 100 can be any surface acoustic wave resonator disclosed herein. Any suitable number of series SAW resonators and shunt SAW resonators can be included in a transmit filter 100.

FIG. 8B is a schematic diagram of a receive filter 105 that includes surface acoustic wave resonators according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. For instance, one or more of the SAW resonators of the receive filter 105 can be a surface acoustic wave device disclosed herein. Alternatively or additionally, one or more of the SAW resonators of the receive filter 105 can be any surface acoustic wave resonator disclosed herein. Any suitable number of series SAW resonators and shunt SAW resonators can be included in a receive filter 105.

Although FIGS. 8A and 8B illustrate example ladder filter topologies, any suitable filter topology can include a SAW resonator in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

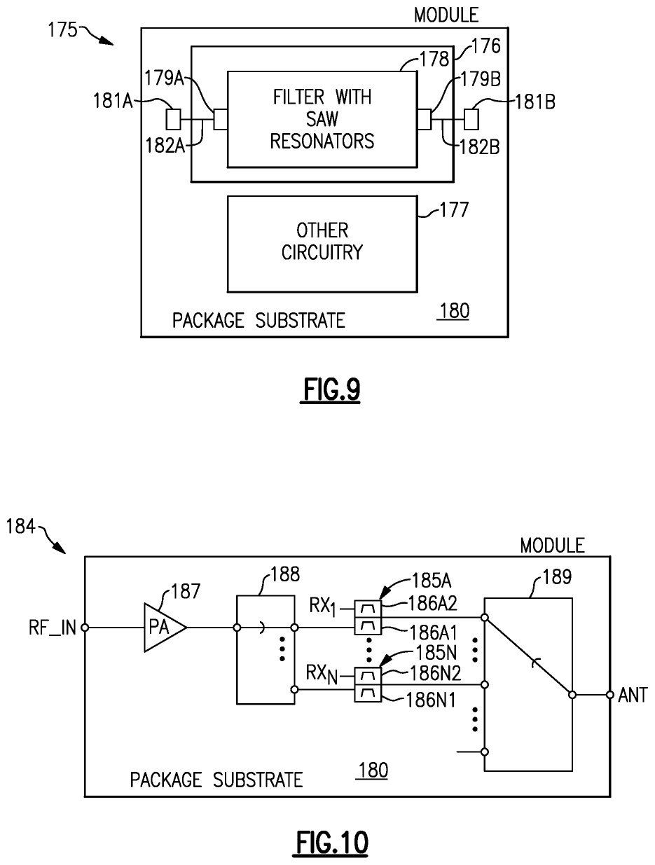

FIG. 9 is a schematic diagram of a radio frequency module 175 that includes a surface acoustic wave component 176 according to an embodiment. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 9 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 9. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

FIG. 10 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 10 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

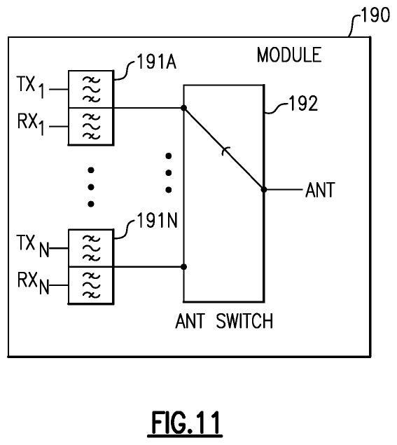

FIG. 11 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

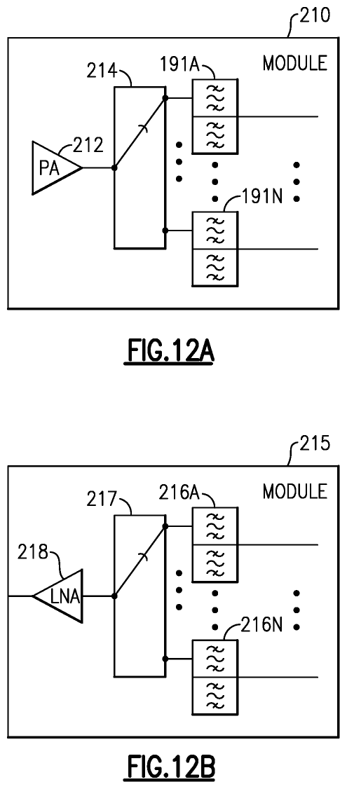

FIG. 12A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 12B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments (not illustrated), one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments (not illustrated), a plurality of low noise amplifiers can be implemented. The module 215 can include diversity receive features in certain applications.

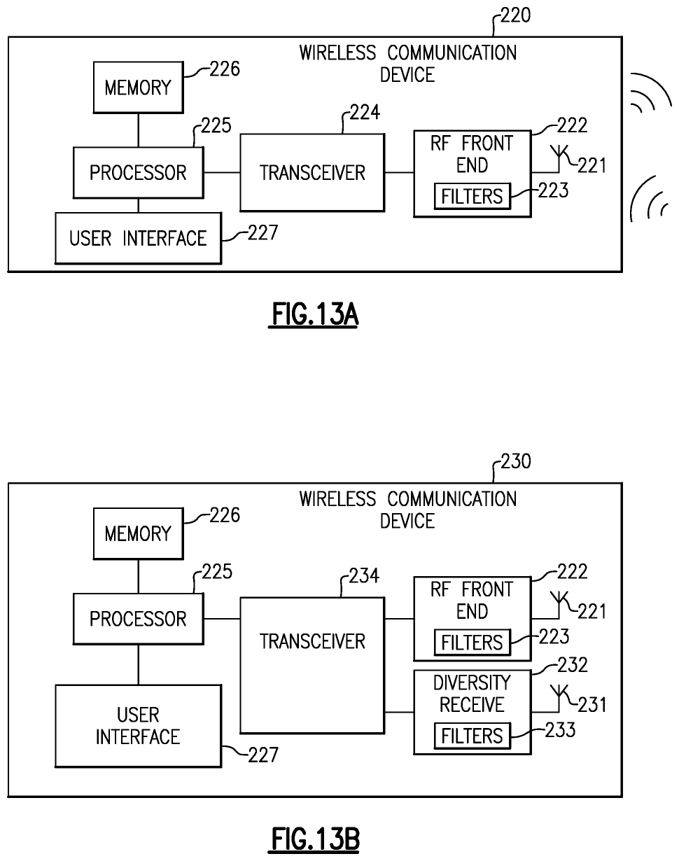

FIG. 13A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 13B is a schematic diagram of a wireless communication device 230 that includes filters 223 in a radio frequency front end 222 and a second filter 233 in a diversity receive module 232. The wireless communication device 230 is like the wireless communication device 200 of FIG. 13A, except that the wireless communication device 230 also includes diversity receive features. As illustrated in FIG. 13B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Although embodiments disclosed herein relate to surface acoustic wave resonators, any suitable principles and advantages disclosed herein can be applied to other types of acoustic wave resonators that include an IDT electrode, such as Lamb wave resonators and/or boundary wave resonators. For example, any suitable combination of features of the tilted and rotated IDT electrodes disclosed herein can be applied to a Lamb wave resonator and/or a boundary wave resonator.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An acoustic wave device configured to generate a wave having a wavelength of L, the acoustic wave device comprising:
a piezoelectric layer;
a first layer of an interdigital transducer electrode formed with the piezoelectric layer, the first layer having a material with a first mass density, the first mass density being greater than 5000 kg/m³, the first layer having a thickness less than 0.04 L; and
a second layer of the interdigital transducer electrode over the first layer, the second layer having a material with a second mass density smaller than the first mass density.

2. The acoustic wave device of claim 1 wherein the first layer of the interdigital transducer electrode is disposed on the piezoelectric layer.

3. The acoustic wave device of claim 1 wherein the first mass density is greater than 8500 kg/m³.

4. The acoustic wave device of claim 3 wherein the first mass density is greater than 10000 kg/m³ and the thickness of the first layer is less than 0.03 L.

5. The acoustic wave device of claim 4 wherein the first mass density is greater than 15000 kg/m³.

6. The acoustic wave device of claim 5 wherein the thickness of the first layer is less than 0.008 L.

7. The acoustic wave device of claim 1 wherein the second material is aluminum and the first mass density is greater than 10000 kg/m³, the thickness of the first layer is in a range between 0.0025 L and 0.03 L.

8. The acoustic wave device of claim 1 further including a functional layer below the piezoelectric layer and a support substrate layer below the functional layer.

9. The acoustic wave device of claim 8 wherein the functional layer is a silicon dioxide layer and the support layer is a silicon layer.

10. The acoustic wave device of claim 1 further including a passivation layer over the interdigital transducer electrode.

11. The acoustic wave device of claim 10 wherein the passivation layer has a first region that is positioned over an edge region and a gap region of the interdigital transducer electrode, and a second region that is positioned over a center region of the interdigital transducer electrode and has a thickness greater than a thickness of the first region.

12. The acoustic wave device of claim 1 wherein the interdigital transducer electrode includes a hammer head shape at an edge region of the interdigital transducer electrode.

13. The acoustic wave device of claim 1 wherein the interdigital transducer electrode includes a thicker interdigital transducer electrode portion at an edge region of the interdigital transducer electrode that has a thickness greater than other portions of the interdigital transducer electrode.

14. An acoustic wave device configured to generate a wave having a wavelength of L, the acoustic wave device comprising:
a piezoelectric layer;
a first layer of an interdigital transducer electrode structure formed with the piezoelectric layer, the first layer having a material with a mass density greater than 8500 kg/m³, the first layer having a thickness less than 0.03 L;
a second layer of the interdigital transducer structure over the first layer, the second layer being an aluminum layer; and
a support substrate layer below the piezoelectric layer.

15. The acoustic wave device of claim 14 wherein the first mass density is greater than 10000 kg/m³.

16. The acoustic wave device of claim 14 further including a passivation layer over the interdigital transducer electrode, the passivation layer is a silicon nitride layer.

17. The acoustic wave device of claim 16 wherein the passivation layer has a first region that is positioned over an edge region and a gap region of the interdigital transducer electrode, and a second region that is positioned over a center region of the interdigital transducer electrode and has a thickness greater than a thickness of the first region, and the interdigital transducer electrode includes a hammer head shape at an edge region of the interdigital transducer electrode.

18. An acoustic wave device configured to generate a wave having a wavelength of L, the acoustic wave device comprising:
a piezoelectric layer;
a first layer of an interdigital transducer electrode formed with the piezoelectric layer, the first layer having a material with a first mass density of ρ, the first mass density of ρ being greater than 5000 kg/m³, the first layer having a thickness of t1 in a range between 0.0025 L(10220/ρ) and 0.04 L(10220/ρ); and
a second layer of the interdigital transducer electrode over the first layer, the second layer having a material with a second mass density smaller than the first mass density.

19. The acoustic wave device of claim 18 wherein the first mass density of ρ is greater than 8500 kg/m³.

20. The acoustic wave device of claim 19 wherein the first mass density of ρ is greater than 10000 kg/m³ and the thickness of t1 is less than 0.03 L(10220/ρ).
